(19) United States
(12) Patent Application Publication
(10) Pub. No.: US 2012/0070565 A1
(43) Pub. Date: Mar. 22, 2012

(54) OPERATIONALLY RELIABLE COATING DEVICE FOR POWDERY MATERIAL

(75) Inventors: Heinz MEIER, Zurich (CH); Christian Bürge, Schafisheim (CH); Beat Schnider, Luzern (CH)

(73) Assignee: Sika Technology AG, Baar (CH)

(21) Appl. No.: 13/236,144

(22) Filed: Sep. 19, 2011

Related U.S. Application Data
(63) Continuation of application No. PCT/EP2010/053583, filed on Mar. 19, 2010.

(30) Foreign Application Priority Data
Mar. 19, 2009 (EP) 09155600.1

(51) Int. Cl. C23C 16/52; B05D 7/00; B05C 11/00

(52) U.S. Cl. 427/8; 118/75; 427/212

(57) ABSTRACT

A device for coating powdery material with at least one liquid additive, said device including a conveying device which contains a conveyor line which transports the powdery material, in addition to an introduction device for introducing the liquid additive onto the conveyor line comprising the powdery material, also including a cleaning device for cleaning the introduction device. Said introduction device includes a supply line and at least two nozzles, said liquid additive can be introduced onto the conveyor line and added to the powdery material by means of at least one nozzle. Also disclosed are a method for coating powdery material with at least one liquid additive and the use of a device for coating powdery material with at least one liquid additive.

### RELATED APPLICATIONS

This application claims priority as a continuation application under 35 U.S.C. §120 to PCT/EP2010/053583, which was filed as an International Application on Mar. 19, 2010 designating the U.S., and which claims priority to European Application No. 09155600.1 filed in Europe on Mar. 19, 2009. The entire contents of these applications are hereby incorporated by reference in their entireties.

### FIELD

The disclosure relates to a device for treating, for example, coating, powdery material with at least one liquid additive. The device comprises a conveying device which contains at least one conveyor line through which the powdery material is conveyed, and at least one introduction device for introducing the liquid additive into the at least one conveyor line.

The disclosure further relates to a method for treating powdery material with at least one liquid additive and use of a device for treating powdery material with at least one liquid additive.

### BACKGROUND INFORMATION

Cement material is usually extracted from cement clinker. Cement clinker, the preproduct from the cement rotary kiln, is ground to cement powder, then mixed with plaster, which functions as a quick-setting agent, with cement being created as the end product via the mixing process. The cement extracted is stored in silos following production. In subsequent processing into concrete, the cement material is mixed with aggregates, chemical additives and water. Admixing additives is meant to improve concrete characteristics in a chemical and/or a physical respect. In this manner additives are capable, for example, of influencing the flow characteristic, the viscosity, the compaction behavior and the setting behavior of said concrete.

Admixing liquid additive during subsequent processing, for example during conveying, is difficult as the powdery materials required for producing concrete, for example their dust, may react with the liquid additive and affect the introduction of said liquid additive by contamination of the introduction device. High dust concentrations and/or high temperatures typically exist for example when the powdery materials required for producing concrete are conveyed pneumatically, which is conducive to formation of the above-mentioned contaminations.

The introduction device can become contaminated or introduction of the liquid additive can be impeded due to the liquid additive itself, for example if it fails or due to any contamination contained therein. A reliable and controllable introduction of the liquid additive can be beneficial for a consistent quality of the final product.

### SUMMARY

According to an exemplary aspect, a device for treating or coating a powdery material with at least one liquid additive is provided comprising:

a conveying device including at least one conveyor line through which the powdery material is conveyed;

at least one introduction device for introducing the liquid additive into the at least one conveyor line comprising the powdery material; and

at least one cleaning device for cleaning the introduction device,

wherein the introduction device comprises a supply line and at least two nozzles, wherein at least one nozzle can introduce the liquid additive into the conveyor line and to the powdery material.

According to an exemplary aspect, a method for treating or coating powdery material with at least one liquid additive is provided, comprising contacting a liquid additive with a powdery material using a device, wherein the device comprises:

a conveying device including at least one conveyor line through which the powdery material is conveyed;

at least one introduction device for introducing the liquid additive into the at least one conveyor line comprising the powdery material; and

at least one cleaning device for cleaning the introduction device,

wherein the introduction device comprises a supply line and at least two nozzles, wherein at least one nozzle can introduce the liquid additive into the conveyor line and to the powdery material.

### BRIEF DESCRIPTION OF THE DRAWINGS

Exemplary embodiments of the disclosure will be illustrated in more detail in the drawings below. Like reference numerals indicate like elements in the different figures. The media flow direction is shown by arrows.

FIG. 1 illustrates a schematic diagram of an exemplary embodiment;

FIG. 2a and FIG. 2b are side views of exemplary movable shaped parts;

FIGS. 3a to 3c are views of exemplary nozzles including protective device;

FIG. 4a and FIG. 4b are views of an exemplary nozzle including cleaning device and protective device;

FIG. 5 is a view of an exemplary nozzle including an exemplary cleaning device;

FIG. 6 is a schematic diagram of an exemplary embodiment.

### DETAILED DESCRIPTION

According to an exemplary embodiment, disclosed is a device for providing a controlled, reliable and constant treatment of the powdery material with a liquid additive.

The device 1 includes at least one cleaning device 7 for cleaning the introduction device 6, and the introduction device 6 comprises a supply line 8 and at least two nozzles 9, wherein at least one nozzle 9 can introduce the liquid additive 3 onto the conveyor line 5 and to the powdery material 2.

Exemplary aspects of the disclosure are, inter alia, that the inner 21 and outer 31 contaminations, which occur frequently, can be eliminated by the cleaning device 7 and/or prevented, thus ensuring constant treatment of the powdery material 2 with liquid additive 3.

As the device comprises at least two nozzles 9, the decrease in conveying capacity of the liquid additive 2 can be compensated by contamination and/or cleaning of a nozzle by another nozzle, which consequently ensures reliable treatment of the powdery material 2 with liquid additive 3.

The device thus is provided, for example, to prevent and/or eliminate and/or compensate a decrease in conveying capacity of the liquid additive 2 by contaminations of the conveying device.

The cleaning device 7 can clean the introduction device 6 permanently over time or in regular intervals to prevent contaminations occurring. To prevent contaminations, said device can include protective devices 13 for the nozzles 9 in the conveyor line 5.

At least one of said nozzles 9 can be disposed movably into and out of the conveyor line 5. It can be, inter alia, conducive to prevention of outer contaminations 31 in that the nozzles, for example, the outlet opening 16, are protected from said dust 20 of the powdery material 2. It also enables the nozzles to be cleaned outside the conveyor line by a cleaning device 7, which thus improves the cleaning environment. Additional nozzles can consequently, if needed or desired, be introduced into, or nozzles be removed from, the conveyor line 5, for example to maintain or change the conveying capacity of the liquid additive 2, while nozzles that are not used can be protected from said dust outside the conveyor line.

At least two nozzles 9 of the introduction device 6 can be disposed on a movable shaped part 15.

If a nozzle 9 is blocked and/or cleaned, the movable shaped part 15 can be advanced by one position to the next nozzle. Hence, down time without any conveying can be shortened significantly, and conveying of the liquid additive 3 continues to be ensured because the possibility to revert to other nozzles of the movable shaped part continues to exist.

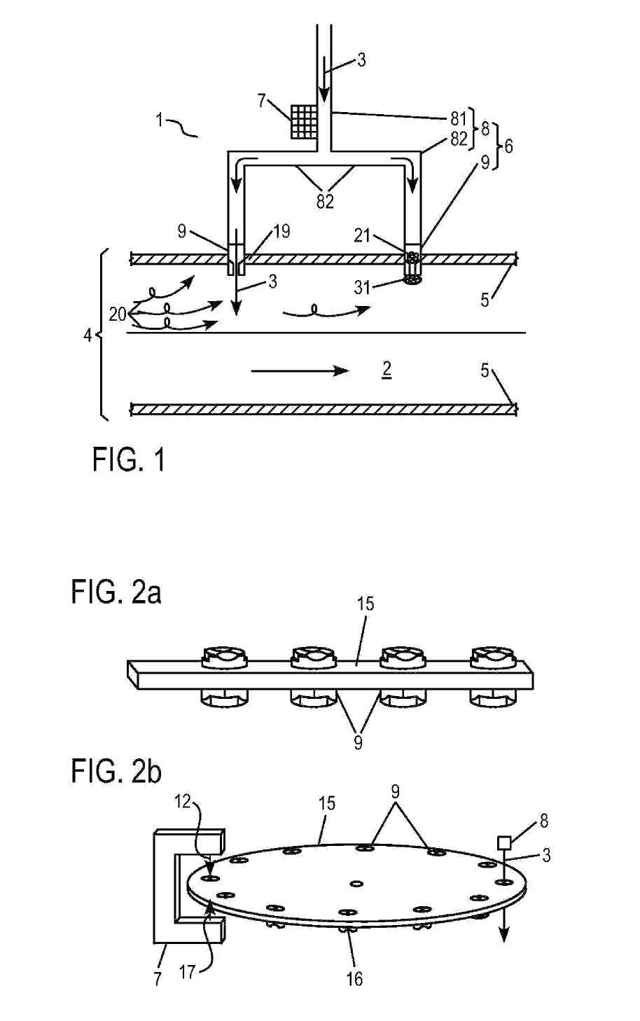

In FIG. 1 the schematic assembly of an exemplary device 1 for treating, for example coating, powdery material 2 with at least one liquid additive 3 is shown. Said device 1 comprises a conveying device 4 which contains at least one conveyor line 5 through which the powdery material 2 is conveyed, and at least one introduction device 6 for introducing the liquid additive 3 into the at least one conveyor line comprising the powdery material 2. Said device 1 includes at least one cleaning device 7 for cleaning the introduction device 6. The introduction device 6 comprises a supply line 8 and at least two nozzles 9, wherein the liquid additive 3 can be introduced onto the conveyor line 5 and to the powdery material 2 via at least one nozzle 9 respectively. In this document “powdery material” is understood as a material which is obtained through disaggregation of a dry solid substance, for example via chopping, pulverizing, pounding or grinding in mills or via spray drying.

Powdery materials can be classified roughly according to grain size; powdery materials can be classified, for example, via their bulk density and via sieve analysis. Powdery materials 2 can have a particle size of about 1-200 μm, for example, 3-30 μm, and/or a fineness according to Blaine of 2000-8000 cm²/g, for example, 3000-6000 cm²/g.

Non-hydraulic, hydraulic and latently hydraulic powdery materials of any type, for example, of the type employed in large amounts for the construction industry, are suitable as powdery material 2.

Further materials suitable as powdery materials 2 are substances which are used to produce concrete, mortar or plaster, for example, cement particles. It is also possible to use substances or additives such as for example silica fume, fly ash, lightweight aggregate, scoria, fiber materials, for example organic ones such as polypropylene fibers etc. or inorganic ones such as basalt, glass etc.

It is possible to treat, for example coat, all substances which are used to produce concrete, mortar or plaster, with a liquid additive 3. Powdery material can be coated where said powdery materials are conveyed pneumatically. That means the treatment process does not necessarily have to occur during concrete, mortar or plaster production. The base substances can hence already be treated at the place of their production. Consequently, the cement particles can for example be treated directly at the end of the cement production process.

The powdery material 2 can comprise at least one bonding agent, which can be selected from the group consisting of cement, mortar, plaster, silica fume, fly ash, scoria and granulated cinder or a mixture thereof. The powdery material 2 can be cement.

Suitable liquid additives 3 can include materials which can be dispersed (aerosol) and/or sputtered (drops) and/or vaporized (vapor) and which have a viscosity of 1-500 mPa*s.

Some liquid additives, whose names in most cases will reveal their effect, will be listed by way of example and without limitation: plasticizer, superplasticizer, air entrainer, (reaction) retarding agent, accelerator such as setting and hardening accelerator, stabilizer, chromate reducer, grouting aids, foaming agent, air-entraining agent, densifier, corrosion inhibitor and recycling aids.

The at least one liquid additive 3 can be selected from the group consisting of dispersing agent, fluidifier, superplasticizer, retarding agent, accelerator, stabilizer, shrinkage reducer, air-entraining agent and corrosion inhibitor or a mixture thereof.

A high-performance concrete plasticizer can be used as liquid additive, for example, the product ViscoCrete® of the company Sika. This high-performance concrete plasticizer can reduce the amount of water required by cement, improving concrete processability.

The conveying device 4, which includes at least one conveyor line 5, through which the powdery material 2 is conveyed, can be a conveying device in the construction industry.

Such a conveying device 4 for example can serve the purpose of transport from production of the powdery material 2 to an interim storage facility, such as an interim silo, to a mobile means of transport, such as for example a lorry or rail carriage, or a final storage facility. Transport of the powdery material 2 in a conveyor line 5 can be effected by means of bucket conveyors, belt conveyors, pneumatically or in so-called pneumatic conveyor ducts, also referred to as “air slides”. Exemplary pneumatic conveyor ducts are, for example, commercially available at the company Mahr GmbH, Germany. Pneumatic conveyor ducts can include rectangular steel pipes having a width of 10-100 cm and a height of 10-100 cm, the powdery material 2 while being conveyed in them has a filling height of typically ¼-¾ of the range intended for the powdery material. Moving the powdery material 2 in a pneumatic conveyor duct can be based on fluidization of the powdery material by means of air as well as slanting of the duct from 5 to 10°, which together with the kinetic energy bringing along the powdery material upon entry into the pneumatic conveyor duct, enables the powdery material to move.

Fluidization can occur by making air pass through from below through the powdery material located on a perforated bottom surface, whereby the particles of the powdery material continue moving up and down within an emerging fluidized bed, thus effectively remaining suspended.

Separation of fluidization air and the powdery material can be effected via a separation mesh of plastic or glass fibers, with the fluidization air being able to pass the mesh, yet not the powdery material 2 to be conveyed.

In the conveyor line 5 temperatures of up to 120° C. can prevail, in addition dust 20 can form from powdery material above said powdery material 2.

In the present document the term “dust” is understood as the unwanted dispersed diffusions of solid substances, for example of powdery material 2, in gases, formed by mechanical processes or by lifting of particles, for example by transport in the conveyor line 5, with the solid substance being dispersed into the ambient air within the conveyor line 5.

For example, the conveyor line 5 is a pneumatic conveyor duct.

Said powdery material 2 can be transported at a constant speed of about 0.5-10 m/s through the conveyor line 5.

Said introduction device 6 for introducing the liquid additive 3 into the at least one conveyor line 5 comprises a supply line 8 and at least two nozzles 9. The liquid additive 3 can be introduced into the conveyor line 5 and to the powdery material 2 via at least one nozzle.

The liquid additive, for example, can be dispersed and/or sputtered and/or vaporized. The coating thickness of the powdery material can be set by means of the varying consistencies using the liquid additive.

The liquid additive 3 can be conveyed to the at least two nozzles 9 via the supply line 8 at a pressure of 1-15 bar, for example, 3-7 bar. The pressure of the supply line can be larger or equal, for example larger than the rated pressure of the nozzles. The introduction device 6 can include a pump 10 for conveying the liquid additive 3 as well as at least one valve 27 in front of at least one nozzle 9. The supply line 8 can include a main supply line 81 as well as ancillary supply lines 82, which connect the main supply line 81 with the nozzles 9.

Suitable nozzles 9 inter alia allow for spraying of the liquid additive 3 at pressures of 1-30 bar, for example, 3-7 bar. Said nozzles can be flat-jet nozzles, fog nozzles or two-phase nozzles, for example, flat-jet nozzles.

Fog nozzles can atomize pressurized liquids into extremely fine drops with a large specific surface.

Two-phase nozzles can be marked by very fine atomization in that liquids are mixed with air or gas. Further, they can produce various spray images, such as for example flat jet, hollow cone or full cone spray images.

Flat-jet nozzles can be marked by even liquid or pressure distribution. Further, they allow for large variability in the spray angle selection. Nozzles can have a spray angle of 30°-120°. Depending on the design of the outlet opening 16 of the nozzle, an elliptic or a rectangular impact area is feasible. Flat-jet nozzles are inexpensive and, due to a defined and well-controllable impact area 16, allow for targeted treatment of the powdery material 2 with the liquid additive 3. For example, contact between the liquid additive 3 and the conveyor line 5, for example the walls and, in case of a pneumatic conveyor duct, the separation mesh, can be avoided. This reduces the risk that conveying of the powdery material 2 might be blocked in that either fluidization of the powdery material 2 is reduced or the powdery material becomes fixed to the walls or agglomerates.

The at least two nozzles typically can have a nozzle bore 161 of 0.1-1 mm.

The nozzles 9 can be arranged on the conveyor line 5 such that the liquid additive 3 may be brought into contact as evenly as possible with as large a portion of the powdery material 2 as possible. The nozzles typically are arranged on the conveyor line wall opposite to the powdery material 2. The nozzles, for example the outlet opening 16, can be located in as great a distance from the powdery material 2 as possible in the conveyor line 5. This, on the one hand, allows for greater flexibility in the treatment with the liquid additive 3; on the other hand, the nozzles thus are less exposed to dust 20 of the powdery material 2, which thereby reduces the likelihood of contamination 31 of the nozzles.

The distance between the outlet opening 16 of the nozzle 9 and the powdery material 2 can depend on the filling height of the powdery material 2, the shape of the cross section of the conveyor line and the spray angle of the nozzle.

At least one of said nozzles 9 can be disposed movably into and out of the conveyor line 5. Consequently, nozzles, for example the outlet opening 16, can be protected from said dust 20 of said powdery material 2. It also enables nozzles to be cleaned outside the conveyor line 5 by a cleaning device 7, which improves the cleaning environment. Moreover, additional nozzles can consequently, if needed or desired, be introduced into, or nozzles be removed from, the conveyor line 5, for example to maintain or change the conveying capacity of the liquid additive 3. In this manner any nozzles that are not used can be protected from said dust 20 of powdery material 2 outside the conveyor line.

For example, movement of the at least one nozzle into or out of the conveyor line 5 can be controlled via a control system 13.

The introduction device 6 can comprise at least three nozzles.

At least two nozzles 9 of the introduction device 6 can be disposed on a movable shaped part 15, wherein the movable shaped part 15 can be round, oval or angular.

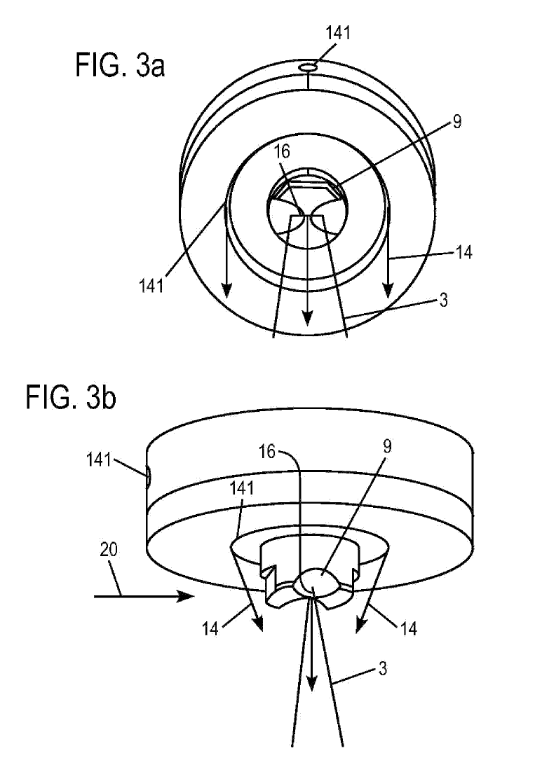

The movable shaped part 15 can be a flat profile or a disc on which several nozzles 9 are mounted, as shown in FIGS. 2a and 2b. The movable shaped part 15 can be arranged on the conveyor line 5 such that nozzles which do not convey any liquid additive 3 are protected from said dust 20 of powdery material. This can for example be achieved by said movable shaped part being fixed to the exterior of the conveyor line and said nozzles which convey liquid additive 3 being moved into the conveyor line via an opening 19 within the conveyor line and spraying liquid additive 3 onto the powdery material 2, while the nozzles which do not convey any liquid additive are located outside the conveyor line 5. The movable shaped part can be fixed to the interior of the conveyor line and a protective device 13, typically a cover, protects said nozzles which do not convey any liquid additive.

If a nozzle 9 is blocked by contamination and/or cleaned, the movable shaped part 15 can be advanced by one switching position to the next nozzle. Hence, down time without any conveying of liquid additive 3 can be shortened significantly. For example, advancing between switching positions via a control system 11 is controllable.

For example, it may be ensured by means of suitable seals that no liquid additive 3 can leak from the nozzles during switching from one nozzle to the next and that no dust 20 of powdery material can come into contact with nozzles that are not in use.

An exemplary aspect of the movable shaped part 15 also is that in case of blockage of a nozzle conveying of the liquid additive 3 can be further ensured as the possibility to revert to other nozzles of the movable shaped part continues to exist.

The nozzles 9, however, can also be worked directly into the movable shaped part 15. Such a design can bring about significant cost savings and can result in sealing the nozzles to prevent leakage of liquid additive 3 from the nozzles during switching from one nozzle to the next.

Device 1 can include a plurality of, for example three or more, movable shaped parts 15.

For example, the supply line 8 includes a valve 27 and/or a device 25 downstream of any movable shaped part for determining the flow rate Fl_{nozzle} of the liquid additive 3 from the conveying nozzle of the movable shaped part 15. For example, if needed or desired, a movable shaped part 15 can be connected or disconnected via said valve 27, and said device 25 for determining the flow rate Fl_{nozzle}, for example, allows for detecting any contamination of the conveying nozzle, so that subsequently, for example, advancing to other switching positions and/or cleaning of the contaminated nozzle can be initiated.

At least one of the nozzles 9 of the above-mentioned device 1 can include a protective device 13, with the protective device 13 being disposed in the conveyor line 5. Said protective device for example serves to protect the nozzle, for example the outlet opening 16, from said dust 20 of said powdery material 2. The protective device 13 can be a cover or an air curtain 14, for example an air curtain.

The protective device 13 can be controllable by a control system 11.

A cover can shield a nozzle, for example an outlet opening 16, substantially completely from dust 20 and for example is used for nozzles that are not used. This solution is simple, effective and inexpensive.

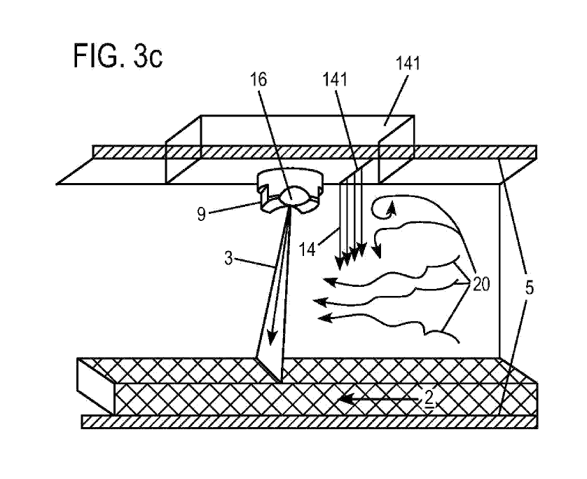

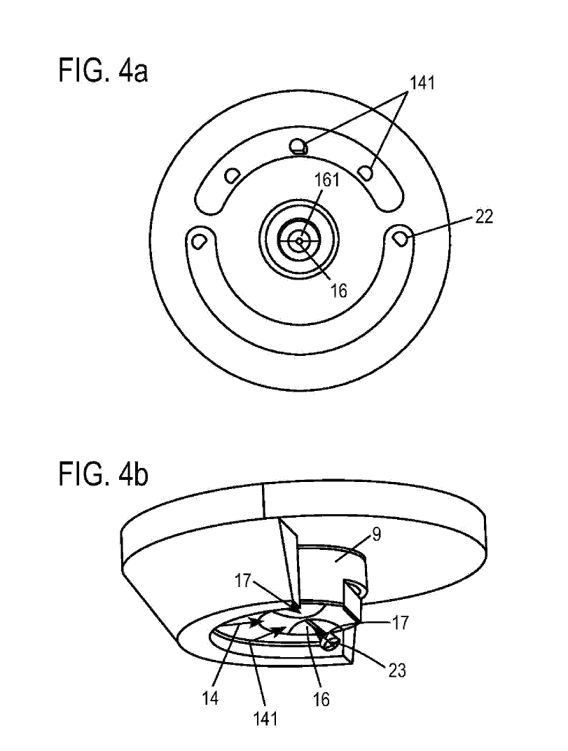

An air curtain 14 can surround a nozzle 9, for example the outlet opening 16, partially or completely, as shown in FIG. 4b by way of example. Moreover, the air curtain 14 can be arranged substantially parallel, as for example in FIG. 3c, concentrically, as for example in FIG. 3a, conically, as for example in FIG. 3b, or orthogonally, as for example in FIG. 4b, towards the axis of the outlet opening of said liquid additive 3 from the nozzle.

FIG. 4a shows, inter alia, the inner part of a nozzle 9 including the nozzle bore and the inner part of the outlet opening 161. Bores of the blow-out device 141 of the air curtain 14 and bores for the pressurized air supply line 22 for cleaning the nozzle are arranged round the nozzle bore 161. FIG. 4b shows the outlet opening 16. An air curtain 14 is formed through the blow-out device 141 substantially orthogonal to the axis of the exit direction of the liquid additive 3.

FIG. 3a shows a blow-out device 141, which forms an air curtain 14, including its axis, substantially parallel to the axis of the exit direction of the liquid additive 3.

FIG. 3b shows a blow-out device 141, which forms an air curtain 14 that is substantially conical to the axis of the exit direction of the liquid additive 3. In such an air curtain orientation, the outlet opening 16 of the nozzle is protected from said dust 20 from all sides.

FIG. 3c shows a blow-out device 141, which forms an air curtain 3, including its axis, substantially parallel to the axis of the exit direction of the liquid additive 3 and is arranged in the transport direction of the powdery material 2 upstream of the nozzle.

An air curtain 14 exits the blow-out device 141 at a pressure of, for example, 0.1-1 bar.

Said device 1 includes at least one cleaning device 7 for cleaning the introduction device 6. The cleaning device 7 may comprise a means 12 for cleaning the introduction device 6, which is selected from the group consisting of sieve, solvent, pressurized air, mechanical tool and ultrasonic sound, for example, pressurized air.

Further, said cleaning device 7 can clean components or the entire introduction device 6 as needed or desired and/or permanently over time or in regular intervals, and said cleaning device 7 can be controlled by a control system 11.

Said cleaning device 7 can further be arranged within or outside the conveyor line 5.

Such means 12 can be used for cleaning the supply line 8 and/or the nozzles 9.

Typical contaminations are inner contaminations 21 and outer contaminations 31. In the present document inner contamination 21 includes contaminations that are located in the supply line 8 or within the nozzle 9, typically in the nozzle bore 161. Inner contaminations 21 can be caused by contaminations in the liquid additive 3 or by a failed liquid additive. Such inner contaminations can block the main supply line 81, thus interfering with the inflow to all nozzles blocking ancillary supply lines 82 or the nozzles 9 themselves inside.

In the present document outer contamination 31 includes contaminations that are located on the outer nozzle part, for example at the outlet opening 16, which comes into contact with said dust 20 of powdery material 2. Such outer contaminations 31 can be caused by dust deposits and for example by accumulations, typically drops, of liquid additive on the nozzle, which due to the dust 20 and within a short time result in agglomerations, which can block the nozzle on its exterior.

Blockage due to inner contaminations 21 could be prevented by means of a sieve or filter, typically made of metal or plastic. Of course, the viscosity of the liquid additive 3 and the size of the outlet opening 16 of the nozzle can be taken into consideration when the sieve aperture is selected.

Another means 12 for cleaning the introduction device 6 is pressurized air 17, which is pumped through the introduction device 6. This can occur periodically, for example to prevent blockage, or in case of current blockage. In this manner, for example, liquid additive 3 could be conveyed through the supply line 8 recurrently for 10 seconds and then pressurized air for 1 second. Switching of any valves 27 to accomplish same may, for example, be achieved simply by means of a valve either opened or closed in rest position. Pressurized air can exit the supply line 8 through the nozzles 9. Further, pressurized air can be channeled through the entire supply line 8 and only through certain areas 5 such as for example the area in front of a nozzle 9. In the latter case, a nozzle blocked by interior contamination 21 from within can be blown out specifically with pressurized air 17. The nozzle can be located within or outside the conveyor line 5. In an exemplary embodiment, blowing out the nozzle outside the conveyor line would not interfere with transport of the powdery material 2.

FIG. 2b shows a cleaning device 7 for the nozzles 9 of a movable shaped part 15, which cleans nozzles 9 located outside the conveyor line 5 with pressurized air 17. Both inner 21 and outer 31 contaminations can be eliminated by the cleaning device shown. The cleaning device 7 shown could also be used to check using pressurized air 17 whether the nozzle is free from contaminations, for example whether cleaning was successful, with the result that pressurized air 17 can pass through the nozzle unimpededly.

FIGS. 4a and 4b, inter alia, show a nozzle 9, next to which a cleaning device 7 is disposed. Pressurized air 17 is supplied through the pressurized air supply line 22 and exits through the pressurized air outlet opening 23, with said pressurized air 17 being conveyed to the outlet opening 16 so as to clean it from outer contaminations 31. Such cleaning by means of pressurized air 17 can occur both within and outside the conveyor line 5.

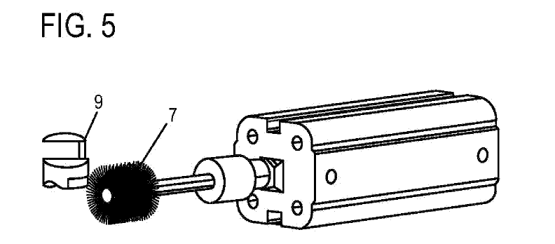

Such means 12 further can be a means for mechanical cleaning, for example ultrasonic sound or a brush, as shown in FIG. 5, which can be disposed within or outside the conveyor line 5.

Such means 12 can also be water, detergents, solvents or mixtures. For example, the nozzle, for example the outlet opening 16 and/or the nozzle bore 161, can be cleaned outside the conveyor line by means of water, detergents, solvents or mixtures thereof, which eliminate inner 21 and outer 31 contaminations.

It is evident that a combination of the means 12 mentioned may also be used.

For example, said device 1 can include a device 24 for determining the flow rate Fl_{FZ} of the liquid additive 3, for example a flow meter, and a device 26 for determining the conveying pressure P_{FZ} of the liquid additive 3, for example a manometer.

For example, said device 1 can include a device 25 for determining the flow rate Fl_{nozzle} of the liquid additive 3, for example a flow meter, of at least one nozzle, for example each nozzle.

For example, said device 1 can include a device 32 for determining the flow rate Fl_{PM} of the powdery material 2, for example a flow meter for powdery media.

Said device 1 may further include at least one control system 11 which as measurement parameter includes the flow rate Fl_{FZ} of the liquid additive 3 and/or the conveying pressure P_{FZ} of the liquid additive and/or the flow rate Fl_{PM} of the powdery material 2.

The at least one control system 11 can include the conveying pressure P_{FZ} of the liquid additive as measurement parameter.

The at least one control system 11 as control variable can connect or disconnect at least one nozzle 9 and/or as control variable can connect or disconnect at least one cleaning device.

An increased conveying pressure P_{FZ} can indicate either blockage in the introduction device 6 or alternatively an increased flow rate Fl_{FZ}, which is caused by an increased flow rate Fl_{PM} of the powdery material 2.

The control system 11 can include the conveying pressure P_{FZ} of the liquid additive as measurement parameter. If a conveying pressure P_{FZ} of the liquid additive 3 is used as measurement parameter, another nozzle 9 can be connected (cascade) once a defined upper conveying pressure P_{FZ O} as opposed to normal or optimal operation is reached, so that subsequently said conveying pressure P_{FZ} due to the larger outlet area falls back again into the normal value range P_{FZ opt} and the spray image remains in a safe range. This means, inter alia, that for example a deliberate flat jet does not exit as a concentrated jet or uncontrolled spray image. Vice versa, a decreased conveying pressure P_{FZ} has an analogous effect.

Further, if a defined upper conveying pressure P_{FZ O} as opposed to normal or optimal operation is reached, a cleaning device 7 as measurement parameter can be connected, so that subsequently the conveying pressure P_{FZ} due to elimination of a contamination in case of inner or outer contamination, falls back again into the normal value range P_{Fz opt}. Conveying a liquid additive within a normal value range P_{FZ opt} can be beneficial in that the nozzles, for example if they are a flat-jet nozzles, include a pressure area or flow-through area respectively in which an optimal spray image is ensured. Outside the areas mentioned, for example, the conveying device or the nozzles can be contaminated or the conveyor line 5 can become oversaturated locally with liquid additive 3. For example, this would not be conducive to a controllable introduction of liquid additive and a homogeneous distribution of the liquid additive on the powdery material.

Admixing the liquid additive 3 alone, based on a determination of the flow rate Fl_{FZ} of the liquid additive may also be envisaged (more flow-through can require more open nozzles); it would, however, allow neither for connecting another nozzle or connecting a cleaning device if a nozzle 9 is blocked, so that subsequently the nozzles would convey outside the normal value range P_{Fz opt}. In addition, the conveying pressure P_{FZ} might increase so much that the introduction device would be damaged and treatment of the powdery material with liquid additive would be stopped.

The flow Fl_{PM} of the powdery material 2 may be determined empirically or technically, for example by a flow meter for powdery media.

The mass ratio of any added liquid additive 3 to powdery material 2 can be 1:10-1:1000, for example 1:100-1:500.

If a maximum conveying pressure P_{Fz max} of the liquid additive 3 is set and conveying of the liquid additive is stopped once the maximum conveying pressure P_{FZ max} is reached, for example by blockage in the main supply line 81, damage to the introduction device 6 can be prevented.

Determining the flow rate Fl_{nozzle} of the liquid additive 3, typically directly upstream of the nozzle 9, can be by means of simple flow sensors, which only have to detect substantial changes in the flow rate Fl_{nozzle} and therefore are inexpensive. The flow rate Fl_{nozzle} therefore can be used to detect inner or outer contaminations of the nozzles.

The control system 11 therefore, as mentioned above, can utilize use of the cleaning devices 7 and/or use of the protective devices 13 as control variables. For example, the control system 11 as control variables includes the devices mentioned and connecting or disconnecting of nozzles 9.

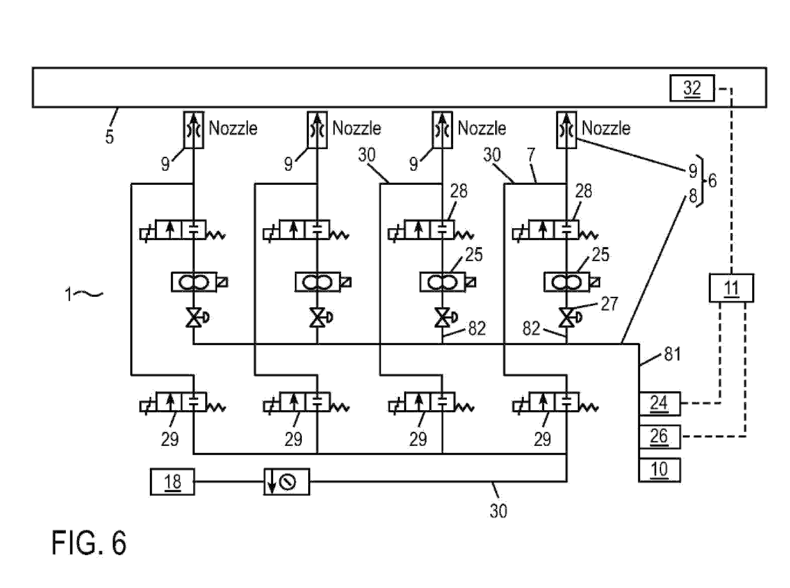

FIG. 6 illustrates an introduction device 6 and a cleaning device 7, which uses pressurized air 17 as means 12. The introduction device 6 comprises a supply line 8, which includes a main supply line 81 as well as ancillary supply lines 82 and nozzles 9.

Further, FIG. 6 illustrates a device for determining the flow rate Fl_{FZ} 24 of the liquid additive 3, of the conveying pressure P_{FZ} 26 of the liquid additive, of the flow rate Fl_{PM} 32 of the powdery material 2 and of the flow rates Fl_{nozzle} 25. Such device 25 can be a simple flow sensor, as mentioned above. The ancillary supply lines 82 further include a valve 27, typically a manually actuated valve, and a 1-way valve 28.

The cleaning device 7 includes pressurized air supply lines 30, which are equipped with 1-way valves 29 and can introduce pressurized air into the area of the ancillary supply line 82 between the nozzle and 1-way valves 28.

Inner or outer contamination due to the decreased flow rate Fl_{nozzle} caused thereby can be established by device 25 for determining the flow rate Fl_{nozzle}. The control system on the one hand can connect an additional nozzle to ensure the desired conveying pressure P_{FZ} and/or the desired flow rate Fl_{FZ}, on the other hand the ancillary supply line 82 concerned can be closed in that the 1-way valve 28 is closed, and pressurized air 17 can be admitted to the blocked ancillary supply line 82 in that the corresponding 1-way valves 29 are opened to clean the ancillary line and/or the nozzle.

According to an exemplary aspect, a method is disclosed for treating, for example coating, powdery material 2 with at least one liquid additive 3, wherein the liquid additive 3 is brought into contact with the powdery material 2 via a device 1 as described above.

For example, the method comprises the steps of:

a. Conveying powdery material 2 through a conveyor line 5;

b. Spraying on powdery material 2 with at least one liquid additive 3 in an amount which is proportional to the flow rate Fl_{PM} of the powdery material.

The method can comprise the step of:

c. Determining the flow rate Fl_{PM} of the powdery material 2 and/or determining at least one conveying parameter FP_{FZ} of the liquid additive 3, wherein FP_{FZ} comprises the two parameters flow rate Fl_{FZ} of the liquid additive 3 and conveying pressure P_{FZ} of the liquid additive 3.

The step can comprise determining the flow rate Fl_{PM} of the powdery material 2, determining the flow rate Fl_{FZ} of the liquid additive 3 and determining the conveying pressure P_{FZ} of the liquid additive 3.

The method can comprise at least one of the steps of:

d. Cleaning parts or the entire introduction device 6 by the cleaning device 7 if at least one conveying parameter FP_{FZ} of the liquid additive 3 falls below a threshold value FP_{FZ min} or exceeds a threshold value FP_{FZ max}, for example if the conveying pressure P_{FZ} of the liquid additive 3 exceeds a threshold value P_{FZ max}; and/or

e. Cleaning parts or the entire introduction device 6 by a cleaning device 7 in regular time intervals.

The method can comprise at least one of the steps of:

f. Arranging another nozzle 9 in the conveyor line 5 if at least one conveying parameter FP_{FZ} of the liquid additive 3 falls below a threshold value FP_{Fz min} or exceeds a threshold value FP_{FZ max}, for example if the conveying pressure P_{FZ} of the liquid additive 3 exceeds a threshold value P_{FZ max} and/or

g. Replacing a nozzle 9 in the conveyor line 5 by another nozzle in the conveyor line 5 if at least one conveying parameter FP_{FZ} of the liquid additive 3 falls below a threshold value FP_{FZ min} or exceeds a threshold value FP_{FZ max}, for example if the conveying pressure P_{FZ} of the liquid additive 3 exceeds a threshold value P_{FZ max}.

The method can comprise at least one of the steps of:

h. Measuring the flow rate Fl_{nozzle} of the least one nozzle 9, through which the liquid additive 3 is sprayed onto the powdery material 2; and

i. Arranging the nozzle 9 outside the conveyor line 5 and/or cleaning of the nozzle mentioned by the cleaning device 7 if the nozzle in step h) falls below a threshold value Fl_{nozzle min}.

The method can comprise the steps of:

j. Measuring the conveying pressure P_{FZ} of the liquid additive 3; and

k. Switching off conveying of the liquid additive 3 when a maximum conveying pressure P_{FZ max} is reached.

According to an exemplary aspect, the use of a device 1 of the above-described type for treating, for example coating, powdery material 2 with at least one liquid additive 3, is disclosed.

It is evident that the disclosure is not limited to the exemplary embodiments which have been shown and described.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE NUMERALS

1 Device
2 Powdery material
3 Liquid additive
4 Conveying device
5 Conveyor line
6 Introduction device
7 Cleaning device
8 Supply line
81 Main supply line
82 Ancillary supply line
9 Nozzles
10 Pump
11 Control system
12 Means for cleaning the introduction device
13 Protective device
14 Air curtain
141 Blow-out device of the air curtain
15 Movable shaped part
16 Outlet opening nozzle
161 Nozzle bore
17 Pressurized air
18 Compressor
19 Opening in the conveyor line
20 Dust of powdery material
21 Inner contamination
22 Pressurized air supply line
23 Pressurized air outlet opening
24 Device for determining the flow rate Fl_{FZ} of the liquid additive
25 Device for determining the flow rate Fl_{nozzle} of the liquid additive of the nozzle
26 Device for determining the conveying pressure P_{FZ} of the liquid additive
27 Valve
28 1-way valve supply line
29 1-way valve pressurized air
30 Pressurized air supply line
31 Outer contamination
32 Device for determining the flow rate Fl_{PM} of the powdery material

What is claimed is:

1. A device for treating or coating a powdery material with at least one liquid additive comprising:
a conveying device including at least one conveyor line through which the powdery material is conveyed;
at least one introduction device for introducing the liquid additive into the at least one conveyor line comprising the powdery material; and
at least one cleaning device for cleaning the introduction device,
wherein the introduction device comprises a supply line and at least two nozzles, wherein at least one nozzle can introduce the liquid additive into the conveyor line and to the powdery material.

2. The device as defined in claim 1, wherein the device includes at least one control system which as a measurement parameter includes the flow rate Fl_{FZ} of the liquid additive and/or the conveying pressure P_{FZ} of the liquid additive and/or the flow rate Fl_{PM} of the powdery material.

3. The device as defined in claim 1, wherein the device includes a device for determining the flow rate Fl_{FZ} of the liquid additive and a device for determining the conveying pressure P_{FZ} of the liquid additive.

4. The device as defined in claim 1, wherein the cleaning device comprises a means for cleaning the introduction device, which is selected from the group consisting of sieve, solvent, pressurized air, mechanical tool and ultrasonic sound.

5. The device as defined in claim 1, wherein the cleaning device cleans components or the entire introduction device on a continuous basis.

6. The device as defined in claim 1, wherein at least one of the nozzles includes a protective device, wherein the protective device is disposed in the conveyor line.

7. The device as defined in claim 6, wherein the protective device is a cover or provides an air curtain.

8. The device as defined in claim 1, wherein at least one of the nozzles is disposed movably into and out of the conveyor line.

9. The device as defined in claim 1, wherein at least two nozzles of the introduction device are disposed on a movable shaped part.

10. The device as defined in claim 1, wherein the conveyor line is a pneumatic conveyor duct.

11. The device as defined in claim 1, wherein the powdery material comprises at least one hydraulic bonding agent.

12. The device as defined in claim 1, wherein the at least one liquid additive is selected from the group consisting of a dispersing agent, fluidifier, superplasticizer, retarding agent, accelerator, stabilizer, shrinkage reducer, air-entraining agent, corrosion inhibitor and a mixture thereof.

13. Method for treating or coating powdery material with at least one liquid additive, comprising contacting a liquid additive with a powdery material using a device, wherein the device comprises:
a conveying device including at least one conveyor line through which the powdery material is conveyed;
at least one introduction device for introducing the liquid additive into the at least one conveyor line comprising the powdery material; and
at least one cleaning device for cleaning the introduction device,
wherein the introduction device comprises a supply line and at least two nozzles, wherein at least one nozzle can introduce the liquid additive into the conveyor line and to the powdery material.

14. The method as defined in claim 13, further comprising:
conveying powdery material through the at least one conveyor line; and
spraying the powdery material with at least one liquid additive in an amount which is proportional to the flow rate Fl_{PM} of the powdery material.

15. The method as defined in claim 14, further comprising:
cleaning a part or the entire introduction device by the cleaning device, if at least one conveying parameter FP_{FZ} of the liquid additive falls below a threshold value FP_{FZ min} or exceeds a threshold value FP_{FZ max}; and/or
cleaning a part or the entire introduction device by the cleaning device in regular time intervals.

16. The device as defined in claim 3, wherein the device includes a device for determining the flow rate Fl_{PM} of the powdery material.

17. The device as defined in claim 4, wherein the means for cleaning the introduction device includes pressurized air.

18. The device as defined in claim 1, wherein the cleaning device provides pressurized air.

19. The device as defined in claim 5, wherein the cleaning device cleans components or the entire introduction device in regular intervals.

20. The device as defined in claim 7, wherein the protective device provides an air curtain.

21. The device as defined in claim 9, wherein the movable shaped part is round, oval or angular.

22. The device as defined in claim 11, wherein the at least one hydraulic bonding agent is selected from the group consisting of cement, mortar, plaster, silica fume, fly ash, scoria and granulated cinder and a mixture thereof.

23. The method as defined in claim 14, further comprising:
determining the flow rate Fl_{PM} of the powdery material and/or determining at least one conveying parameter FP_{FZ} of the liquid additive, wherein FP_{FZ} comprises the two parameters flow rate Fl_{FZ} of the liquid additive and conveying pressure P_{FZ} of the liquid additive.

24. The method as defined in claim 15, wherein a part or the entire introduction device is cleaned by the cleaning device if the conveying pressure P_{FZ} of the liquid additive exceeds a threshold value P_{FZ max}.
